(19) United States
(12) Patent Application Publication
(10) Pub. No.: US 2026/0068296 A1
(43) Pub. Date: Mar. 5, 2026

(54) SEMICONDUCTOR DIE INCLUDING A TRANSISTOR COUPLED TO A CONTACT LAYER WHEREIN THE CONTACT LAYER INCLUDES A METAL CONTACT HAVING A SIDEWALL WITH A REDUCED HEIGHT TO PROMOTE CONNECTIVITY WITH AN ADJACENT VIA

(71) Applicant: QUALCOMM Incorporated, San Diego, CA (US)

(72) Inventors: Junjing Bao, San Diego, CA (US); Chih-Sung Yang, Hsinchu City (TW); Haining Yang, San Diego, CA (US)

(21) Appl. No.: 18/824,041

(22) Filed: Sep. 4, 2024

(51) Int. Cl. H01L 27/088; H01L 21/768; H01L 21/8234; H01L 23/522; H01L 29/08

(52) U.S. Cl. CPC H10D 84/83; H10D 62/151; H10D 84/0149; H10D 84/038

(57) ABSTRACT

Aspects disclosed include a semiconductor die including a transistor coupled to a contact layer wherein the contact layer includes a metal contact having a sidewall with a reduced height to promote connectivity with an adjacent via. The die comprises the contact layer adjacent to an epitaxial layer of the transistor. The contact layer comprises a metal contact adjacent to the epitaxial layer and having a first height. The metal contact comprises a plurality of sidewalls wherein at least one of the plurality of sidewalls has a second height which is less than the first height resulting in increased metal at a surface of the metal contact. The die further comprising a via layer adjacent to the contact layer. The via layer comprising a via adjacent to the surface of the metal contact increasing the connectivity between the via and the metal contact.

### TECHNICAL FIELD

The technology of the disclosure relates to fabricating a contact layer to contact to a transistor in a semiconductor die.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

The die(s) also includes one or more metallization layers that include a metal layer also referred to as a trench layer. Metal interconnects (e.g., metal traces, metal lines) are formed in the metal layer. One or more metallization layers include a dielectric layer, also referred to as a via layer, which includes one or more vias which couple one or more metal interconnects in one metallization layer with one or more metal interconnects in an adjacent metallization layer. The one or more metallization layers are fabricated in the die(s) utilizing a back end of line (BEOL) process to form a BEOL interconnect structure. An outer metallization layer of the one or more metallization layers includes metal interconnects fabricated during the BEOL process (e.g., pads). The die(s) also includes die interconnects (e.g., balls or pillars) which are supported by metal pads in the outer metallization layer and electrically couple the metal interconnects in the die(s) to the metal interconnects exposed in the outer metallization layer (e.g., pads) of the package substrate or another die.

The die(s) also includes a front-end-of-line (FEOL) structure upon which the BEOL interconnect structure formed is disposed. The FEOL structure includes field-effect transistors (FETs) and a contact layer to couple to nodes of the FETs.

### SUMMARY OF THE DISCLOSURE

Aspects disclosed in the detailed description include a semiconductor die including a transistor coupled to a contact layer wherein the contact layer includes a metal contact having a sidewall with a reduced height to promote connectivity with an adjacent via. Related apparatus and methods are also disclosed. In this regard, in some exemplary aspects disclosed herein, the semiconductor die comprises the transistor having an epitaxial layer. The semiconductor die further comprises the contact layer adjacent to the epitaxial layer. The contact layer includes a metal contact adjacent to the epitaxial layer and having a first height. The metal contact includes a plurality of sidewalls wherein at least one of the plurality of sidewalls has a second height. The second height is less than the first height increasing a surface area of a surface of the metal contact. The semiconductor die further includes a via layer adjacent to the contact layer. The via layer includes a via adjacent to the surface of the metal contact. By utilizing the at least one of the plurality of sidewalls where the second height is less than the first height of the metal contact, the surface of the metal contact has more metal to electrically couple the via increasing the connectivity between the via and the metal contact.

In an aspect, a semiconductor die including a transistor, a contact layer, and a via layer is provided. The transistor comprises an epitaxial layer of a first polarity extending in a first direction and a second direction orthogonal to the first direction. The contact layer extending in the first direction and the second direction adjacent to the epitaxial layer. The contact layer comprises a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height. The via layer extending in the first direction and the second direction adjacent to the contact layer, the via layer comprising a via coupled to the metal contact.

In another aspect, a method of fabricating a semiconductor die is provided. The method includes fabricating a transistor, which comprises fabricating an epitaxial layer of a first polarity extending in a first direction and a second direction orthogonal to the first direction. The method also includes fabricating a contact layer extending in the first direction and the second direction adjacent to the epitaxial layer, wherein fabricating the contact layer comprises fabricating a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height. The method also includes fabricating a via layer extending in the first direction and the second direction adjacent to the contact layer, wherein fabricating the via layer comprises fabricating a via coupled to the metal contact.

In another aspect, another method of fabricating a semiconductor die is provided. The method includes fabricating a transistor, comprising fabricating an epitaxial layer of a first polarity extending in a first direction and a second direction orthogonal to the first direction. The method also includes fabricating a contact layer extending in the first direction and the second direction adjacent to the epitaxial layer, wherein fabricating the contact layer comprises patterning the contact layer to access the epitaxial layer, depositing an insulation material to form a plurality of sidewalls, etching portions of at least one of the plurality of sidewalls, and depositing metal to form a metal contact having a first height, the at least one of the plurality of sidewalls having a second height, wherein the second height is less than the first height. The method also includes fabricating a via layer extending in the first direction and the second direction adjacent to the contact layer, wherein fabricating the via layer comprises fabricating a via coupled to the metal contact.

### BRIEF DESCRIPTION OF THE FIGURES

FIG. 1 is a side view of an integrated circuit (IC) that includes a portion of a die, the die including a transistor coupled to a contact layer including a metal contact having a reduced height sidewall to promote connectivity with an adjacent via;

FIG. 2A is top view a portion of an exemplary field-effect transistor (FET) in a die, the FET coupled to a contact layer including a metal contact having a reduced length sidewall;

FIG. 2B is a side view the exemplary FET in FIG. 2A along cut line A-A′ of the metal contact;

FIG. 2C is a side view the exemplary FET in FIG. 2A along cut line B-B′ which does not include the metal contact;

FIG. 2D is a side view the exemplary FET in FIG. 2A along cut line C-C′ which cuts through the metal contact;

FIG. 3A is a close-up view of an exemplary metal contact such as the metal contact in FIG. 2A, the exemplary metal contact having three sidewalls with reduced height and one sidewall with approximately the same height of the exemplary metal contact;

FIG. 3B is a close-up view of another exemplary metal contact such as the metal contact in FIG. 2A, the exemplary metal contact having four sidewalls with reduced height;

FIG. 3C is a close-up view of another exemplary metal contact such as the metal contact in FIG. 2A, the exemplary metal contact having one sidewall with reduced height and three sidewalls with approximately the same height of the exemplary metal contact;

FIG. 4 is a flowchart illustrating an exemplary fabrication process for fabricating a die including a metal contact, such as the metal contacts in FIGS. 2A-2D, 3A-3C, having reduced length sidewalls to promote connectivity with an adjacent via;

FIGS. 5A-5I is a flowchart illustrating another exemplary fabrication process for fabricating a die including a metal contact, such as the metal contact of FIGS. 2A-2D, 3A-3C, having reduced length sidewalls to promote connectivity with an adjacent via;

FIGS. 6A1-6I3 are exemplary fabrication stages during fabrication of the metal contact according to the fabrication process in FIGS. 5A-5I from three separate perspectives;

FIG. 7 is a block diagram of an exemplary wireless communications device that includes radio-frequency (RF) components deployed in an IC package, wherein the IC package includes a semiconductor die having a metal contact, including, but not limited to, the metal contacts in FIGS. 2A-2D, 3A-3C, having a reduced length sidewall(s) to promote connectivity with an adjacent via and fabricated according to the exemplary fabrication processes in FIGS. 4 and 5A-5I; and

FIG. 8 is a block diagram of an exemplary processor-based system that can include components deployed in an IC package, wherein the IC package includes a semiconductor die having a metal contact, including, but not limited to, the metal contacts in FIGS. 2A-2D, 3A-3C, having a reduced length sidewall(s) to promote connectivity with an adjacent via and fabricated according to the exemplary fabrication processes in FIGS. 4 and 5A-5I.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise. The term “directly adjacent” as used herein means adjoining something as shown in the Figures.

Aspects disclosed in the detailed description include a semiconductor die including a transistor coupled to a contact layer wherein the contact layer includes a metal contact having a sidewall with a reduced height to promote connectivity with an adjacent via. Related apparatus and methods are also disclosed. In this regard, in some exemplary aspects disclosed herein, the semiconductor die comprises the transistor having an epitaxial layer. The semiconductor die further comprises the contact layer adjacent to the epitaxial layer. The contact layer includes a metal contact adjacent to the epitaxial layer and having a first height. The metal contact includes a plurality of sidewalls wherein at least one of the plurality of sidewalls has a second height. The second height is less than the first height increasing a surface area of a surface of the metal contact. The semiconductor die further includes a via layer adjacent to the contact layer. The via layer includes a via adjacent to the surface of the metal contact. By utilizing the at least one of the plurality of sidewalls where the second height is less than the first height of the metal contact, the surface of the metal contact has more metal to electrically couple the via increasing the connectivity between the via and the metal contact.

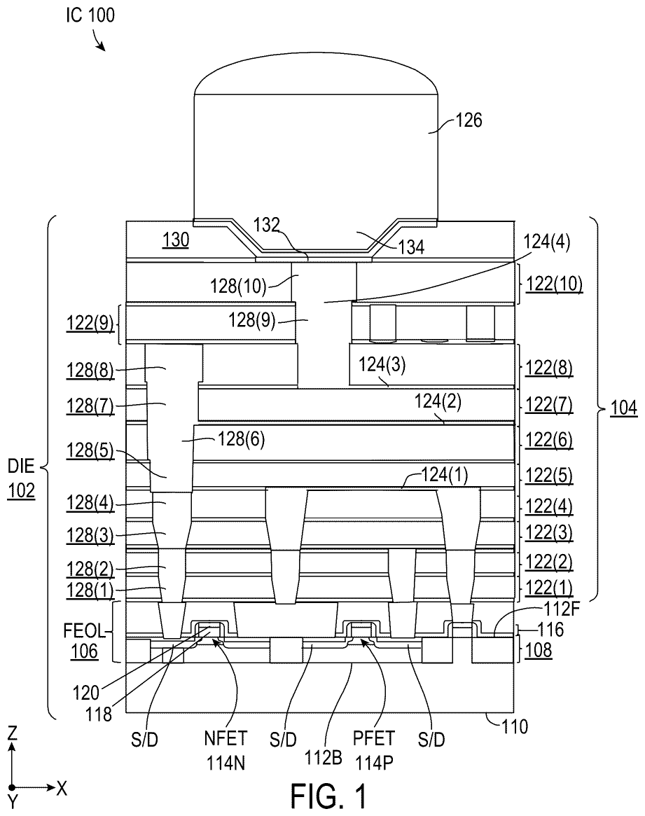

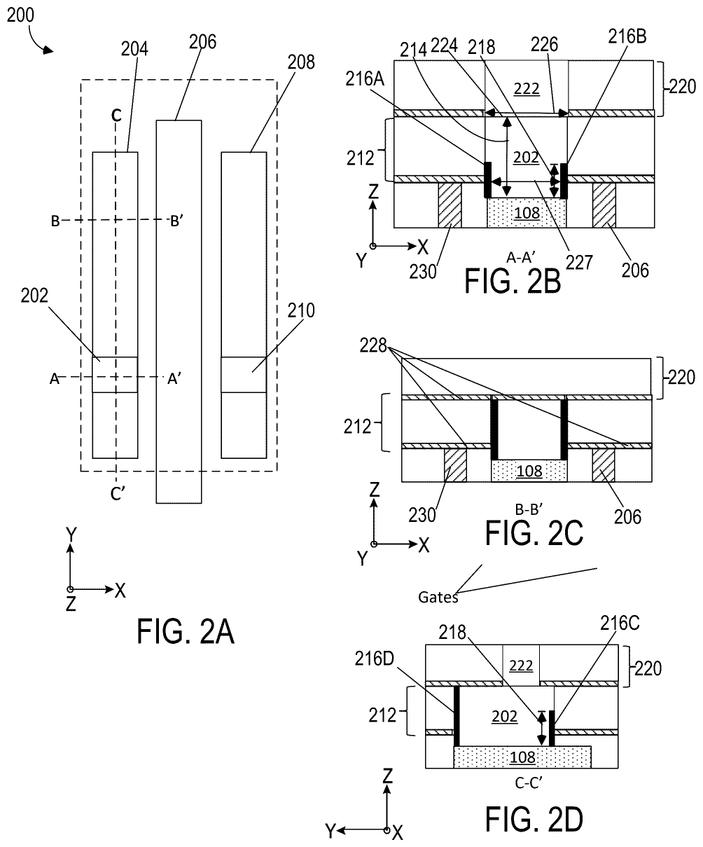

FIG. 1 is a side view of an integrated circuit (IC) 100 that includes a portion of a die 102, the die 102 including a transistor coupled to a contact layer including a metal contact having a reduced height sidewall to promote connectivity with an adjacent via. The die 102 includes a back end of line (BEOL) interconnect structure 104 formed by a BEOL process and disposed on a front-end-of-line (FEOL) structure 106. The FEOL structure 106 includes an active, semiconductor layer 108 that is formed on a substrate 110. The semiconductor layer 108 extends in a first, horizontal direction, which is the X-axis and Y-axis directions as shown in FIG. 1. The semiconductor layer 108 has a first, front side 112F and a second, back side 112B opposite the first, front side 112F in a second, vertical direction (Z-axis direction). P-type field-effect transistors (FETs) (PFETs) and N-type FETs (NFETs) 114P, 114N are formed in the semiconductor layer 108. The FEOL includes a contact layer 116 including a metal contact 118 having a reduced height sidewall (not shown) to promote connectivity with an adjacent via 120 which will be described in more detail beginning in FIGS. 2A-2D. The BEOL interconnect structure 104, as a front side interconnect structure 104, is disposed adjacent to the front side 112F of the semiconductor layer 108 in the second, vertical direction (Z-axis direction). The BEOL interconnect structure 104 facilitates signal routing in the die 102 on the front side 112F of the semiconductor layer 108. In this regard, the BEOL interconnect structure 104 includes a plurality of front side, metallization layers 122(1)-122(10) that each include one or more metal interconnects, such as metal interconnects 124(1)-124(4) that can provide direct or indirect interconnections between the FETs 114P, 114N and die interconnects 126 (e.g., a solder bump) adjacent to an upper metallization layer 122(10) of the BEOL interconnect structure 104. The metal interconnects 124(1)-124(4) extend in the first, horizontal direction(s) (X- and/or Y-axis directions). The BEOL interconnect structure 104 also includes via layers 128(1)-128(10) disposed through the front side metallization layers 122(1)-122(10) to provide interconnects between the metal interconnects 124(1)-124(4) in adjacent metallization layers 122(4)-122(5), 122(6)-122(7), 122(7)-122(8), and 122(9)-122(10), respectively. A first passivation layer 130 extends in the first, horizontal direction adjacent to the outer metallization layer 122(10). A metal pad 132 is disposed between the passivation layer 130 and the outer metallization layer 122(10) to mechanically support the die interconnect 126. The die interconnect 126 couples to the metal pad 132 through a via 134. The metal pad 132 couples to metal interconnect 124(3) through via layer 128(10).

FIG. 2A is top view a portion of an exemplary FET 200, such as the NFET 114N in FIG. 1, in the die 102, the FET 200 coupled to a contact layer (not shown) including a metal contact 202 having a reduced length sidewall. The FET 200 includes a source region 204 coupled to the metal contact 202, a gate region 206, and a drain region 208. Another metal contact 210 couples to the drain region 208.

FIG. 2B is a side view of the exemplary FET 200 in FIG. 2A along cut line A-A′ of the metal contact 202 and will be discussed in connection with FIGS. 2C-2D. FIG. 2C is a side view of the exemplary FET in FIG. 2A along cut line B-B′ which does not include the metal contact 202. FIG. 2D is a side view of the exemplary FET 200 in FIG. 2A along cut line C-C′ which cuts through the metal contact 202.

The FET 200 includes the semiconductor layer 108 (also referenced as epitaxial layer 108). The epitaxial layer 108 has a first polarity and extends in a first direction (X-axis direction) and a second direction (Y-axis direction) orthogonal to the first direction. The die 102 includes a contact layer 212 that extends in the first direction and the second direction adjacent to the epitaxial layer 108. The contact layer 212 includes the metal contact 202 adjacent to the epitaxial layer 108 and has a first height 214 in a third direction (Z-axis direction) orthogonal to the first direction and the second direction. The metal contact 202 comprises a plurality of sidewalls 216A-216D extending in the third direction (Z-axis direction) from the epitaxial layer 108 wherein at least one of the plurality of sidewalls 216A-216C, has a second height 218 in the third direction (Z-axis direction). The second height 218 is less than the first height 214. The second height 218 is greater than or equal to ⅔ of the first height 214 in some implementations. The die 102 also includes a via layer 220 extending in the first direction (X-axis direction) and the second direction (Y-axis direction) adjacent to the contact layer 212. The via layer 220 includes a via 222 coupled to the metal contact 202. The via 222 is proximal in one of the first and second directions (X- and Y-axis directions) to the at least one of the plurality of sidewalls 216A-216C having the second height 218 (see FIGS. 2B and 2D). The via 222 may be a barrierless metal fabricated via a barrierless process such as a selective tungsten process.

The metal contact 202 may be composed of tungsten and is fabricated utilizing a conventional barrier metal process. The metal contact 202 has a surface 224 which couples to the via 222. The surface 224 has a width 226. Since the second height 218 of sidewalls 216A, 216B is less than the first height 214 of the metal contact 202, a width 226 at the surface 224 is larger than a width 227 between the sidewalls 216A-216B in the mid-region of the metal contact 202.

As semiconductor feature sizes scale down, the contact surface width in the first direction (X-axis direction) of conventional metal contacts becomes smaller so that the surface of the via overlaps the surface of the conventional metal contact including the full-length sidewalls of the metal contact impacting the desired height of the via created by a barrierless metal process such as a selective tungsten process creating an under growth defect (also known as a top void defect where the side growth of the via is faster than its height growth). As a result, conventional metal contacts at lower semiconductor feature sizes will pose a challenge for deploying a barrierless metal process when forming a via. Unlike conventional metal contacts which couple to an epitaxial layer, the surface area of the surface 224 of the metal contact 202 is greater than having sidewalls having a height approximately equal to the height of the metal contact 202. The benefits of having a sidewall with reduced height includes increased surface area of the metal contact 202 to increase the conductivity between the via 222 and the metal contact 202 and enabling the via 222 to be a barrierless metal such as tungsten, ruthenium, molybdenum, and the like and deposited using various barrierless metal processes including a selective tungsten process.

The sidewalls 216A-216D include a titanium nitride portion which has a width of approximately 1 nanometer (nm) and is a residual of a barrierless metal process and a silicon nitride inner spacer which is approximately 2 nm. As such, the width in the first and second directions of the sidewalls 216A-216D is approximately 3 nm. The width 226 is approximately 15 nm, and the width 227 is approximately 9 nm. By having reduced height sidewalls 216A-216D, the width 226 of the surface 224 of the metal contact 202 has increased from 9 nm to 15 nm or roughly 67%. Since the width 226 is shown in the first direction and the same width is in the second direction, the area of the surface 224 has increased from 81 nm² (9 nm×9 nm) to 225 nm² (15 nm×15 nm). The first height 214 is approximately 30 nm.

The die 102 also includes hard etch masks 228, such as silicon nitride (SiN) and gate region 206 of FET 200 and a gate region 230 of another FET. As shown in FIG. 2A, the metal contact 202 is coupled to the epitaxial layer 108 which is the source region 204. The metal contact 210 is coupled to an epitaxial layer which is the drain region 208.

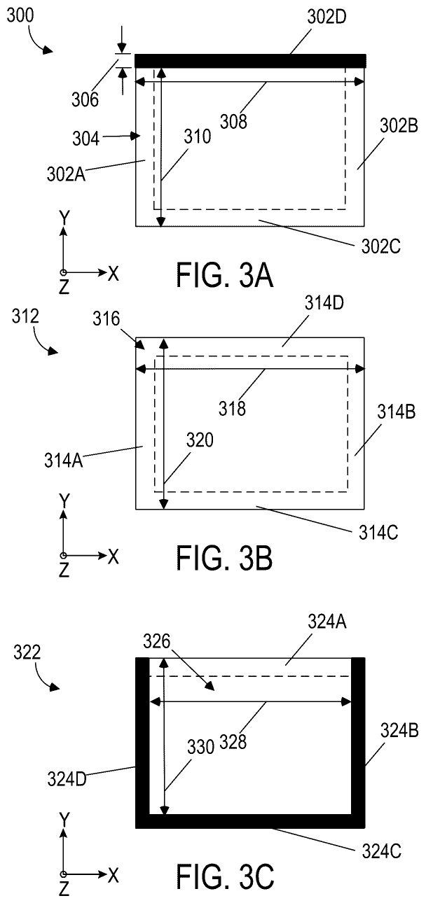

FIG. 3A is a close-up view of an exemplary metal contact 300 such as the metal contact 202 in FIG. 2A. The exemplary metal contact 300 has three sidewalls 302A-302C with a reduced height and one sidewall 302D with approximately the same height of the metal contact 300. The metal contact 300 includes a surface 304 which provides a base for a via to be deposited. The sidewall 302D has a width 306 at the surface 304 in the second direction (Y-axis direction) of approximately 3 nm. The surface 304 has a width 308 in the first direction (X-axis direction) of approximately 15 nm and a length 310 in the second direction (Y-axis direction) of approximately 12 nm yielding an available area of 180 nm² for a via to be deposited.

FIG. 3B is a close-up view of another exemplary metal contact 312 such as the metal contact 202 in FIG. 2A. The exemplary metal contact 312 has four sidewalls 314A-314D with a reduced height. The metal contact 312 includes a surface 316 which provides a base for a via to be deposited. The surface 316 has a width 318 in the first direction (X-axis direction) of approximately 15 nm and a length 320 in the second direction (Y-axis direction) of approximately 15 nm yielding an available area of 225 nm² for a via to be deposited.

FIG. 3C is a close-up view of another exemplary metal contact 322 such as the metal contact 202 in FIG. 2A. The exemplary metal contact 322 has one sidewall 324A with a reduced height and three sidewalls 324B-324D with approximately the same height of the exemplary metal contact 322. The metal contact 322 includes a surface 326 which provides a base for a via to be deposited. The surface 326 has a width 328 in the first direction (X-axis direction) of approximately 9 nm and a length 330 in the second direction (Y-axis direction) of approximately 12 nm yielding an available area of 108 nm² for a via to be deposited. The reduced width 328 and length 330 of the surface 326 is due to the 3 nm widths of the sidewalls 324B-324C. Although not shown in FIGS. 3A-3C, the sidewalls having reduced height, sidewalls 302A-302C, 314A-314D, and 324D, have the second height 218 and sidewalls 302D, 324B-324D have the first height 214 approximately equal to the height of the corresponding metal contact 300, 322.

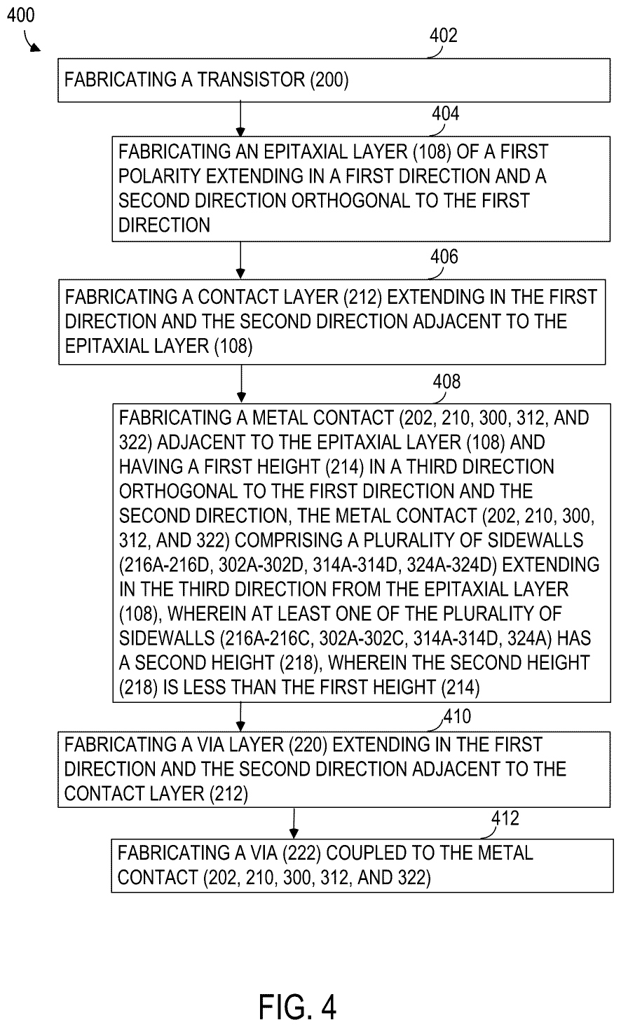

A die including a transistor coupled to a contact layer including a metal contact, including, but not limited to, the metal contacts 202, 210 of FIGS. 2A-2D and the metal contacts 300, 312 and 322 of FIGS. 3A-3C having a reduced height sidewall to promote connectivity with an adjacent via can be fabricated by different fabrication processes. FIG. 4 is a flowchart illustrating an exemplary fabrication process 400 for fabricating a die including a metal contact, such as the metal contacts 202, 210 of FIGS. 2A-2D and the metal contacts 300, 312 and 322 of FIGS. 3A-3C, having reduced length sidewalls to promote connectivity with an adjacent via.

In this regard, a first exemplary step for fabricating a die including a transistor coupled to a contact layer including a metal contact having a reduced height sidewall to promote connectivity with an adjacent via includes fabricating a transistor 200 (block 402 in FIG. 4). Fabricating the transistor 200 may include fabricating an epitaxial layer 108 of a first polarity extending in a first direction and a second direction orthogonal to the first direction (block 404 in FIG. 4). A next step in the fabrication process 400 may include fabricating a contact layer 212 extending in the first direction and the second direction adjacent to the epitaxial layer 108 (block 406 in FIG. 4). Fabricating the contact layer 212 may include fabricating a metal contact 202, 210, 300, 312, and 322 adjacent to the epitaxial layer 108 and having a first height 214 in a third direction orthogonal to the first direction and the second direction, the metal contact 202, 210, 300, 312, and 322 comprising a plurality of sidewalls 216A-216D, 302A-302D, 314A-314D, 324A-324D extending in the third direction from the epitaxial layer 108, wherein at least one of the plurality of sidewalls 216A-216C, 302A-302C, 314A-314D, 324A has a second height 218, wherein the second height 218 is less than the first height 214 (block 408 in FIG. 4). A next step in fabrication process 400 may include fabricating a via layer 220 extending in the first direction and the second direction adjacent to the contact layer 212 (block 410 in FIG. 4). Fabricating the via layer 220 may include fabricating a via 222 coupled to the metal contact 202, 210, 300, 312, and 322 (block 412 in FIG. 4).

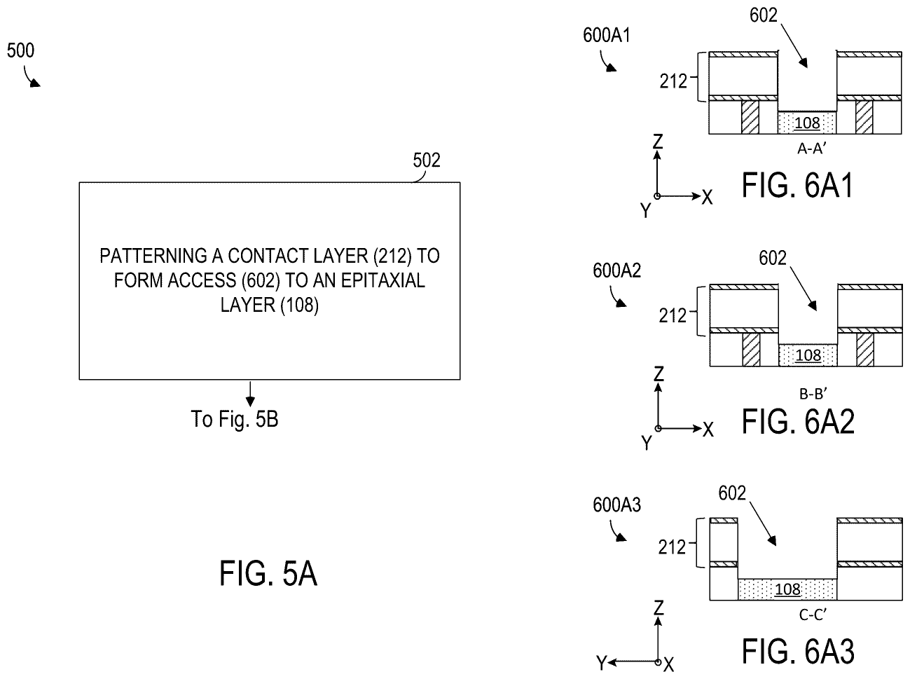

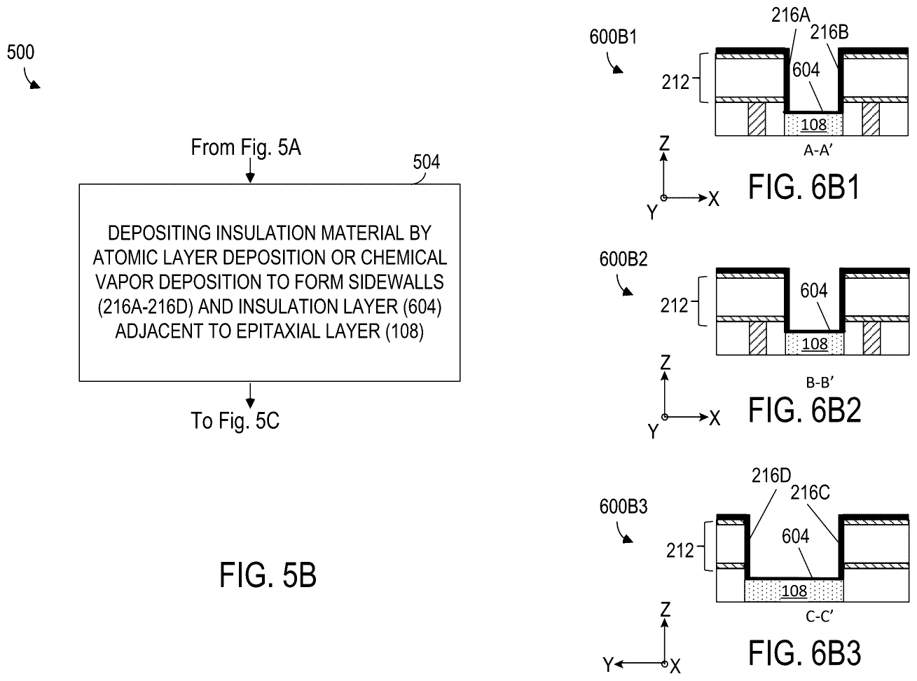

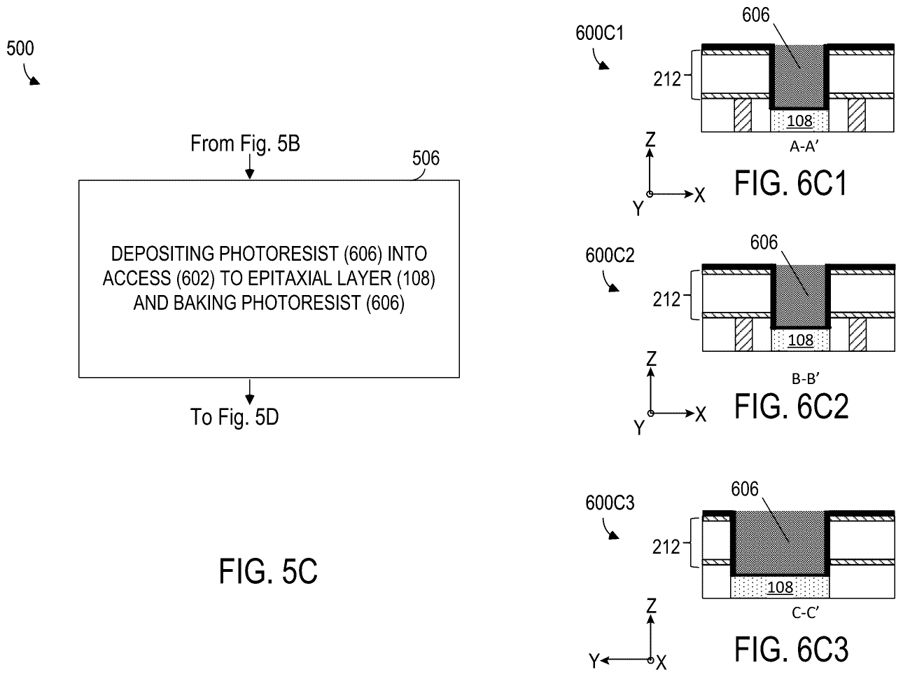

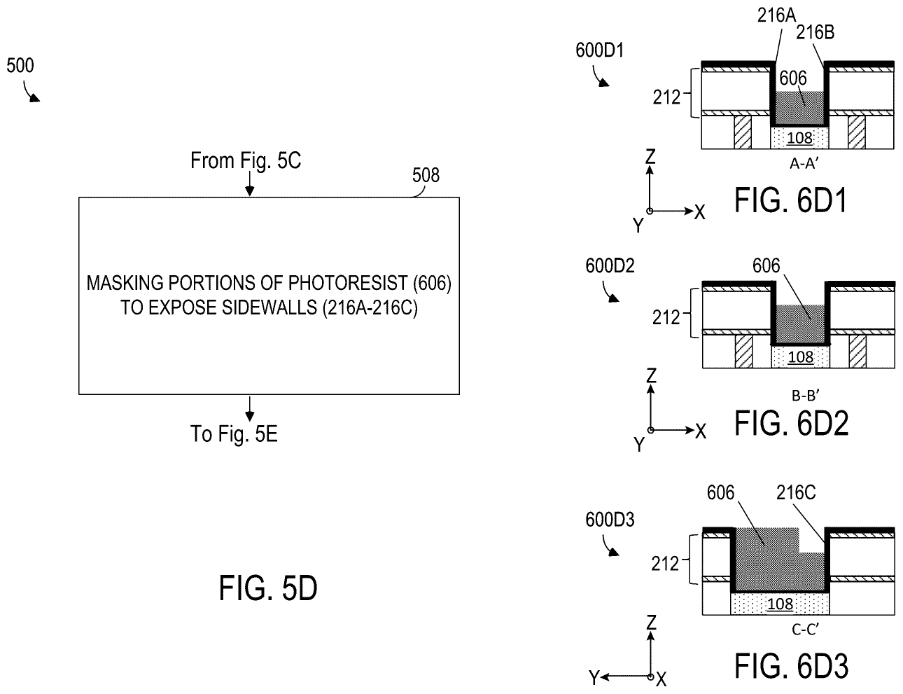

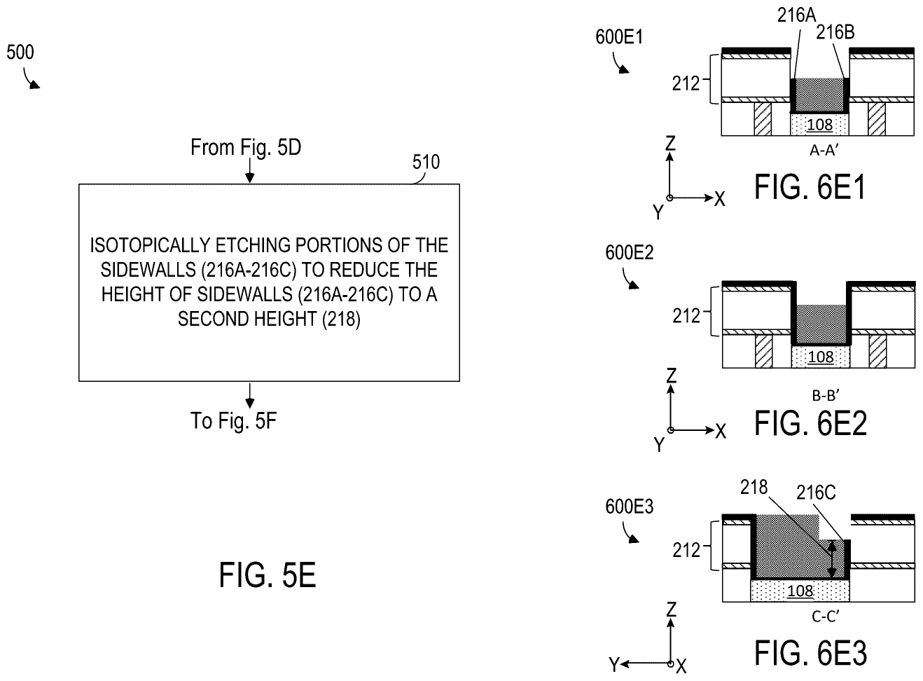

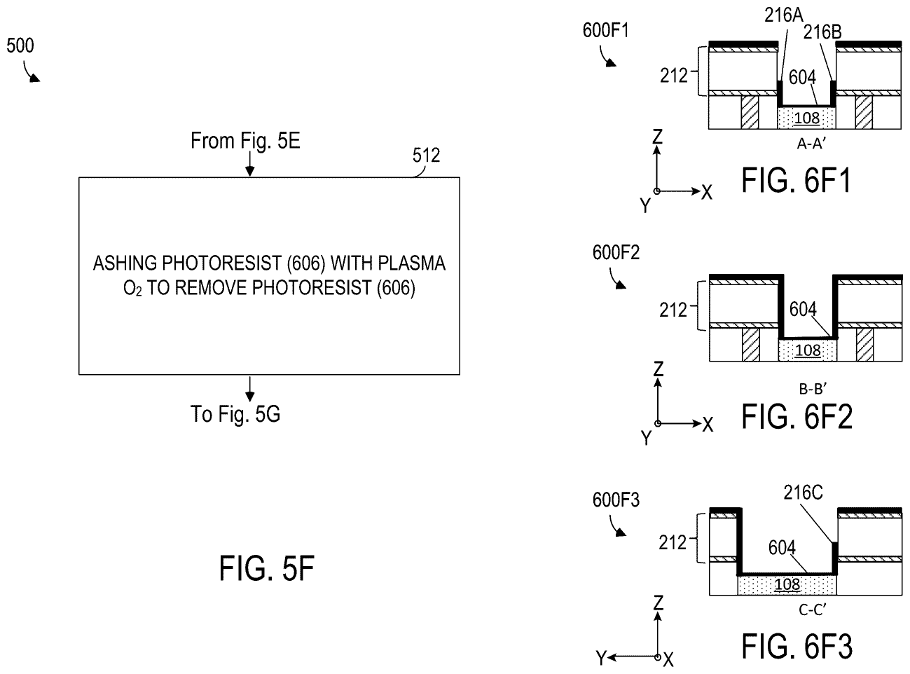

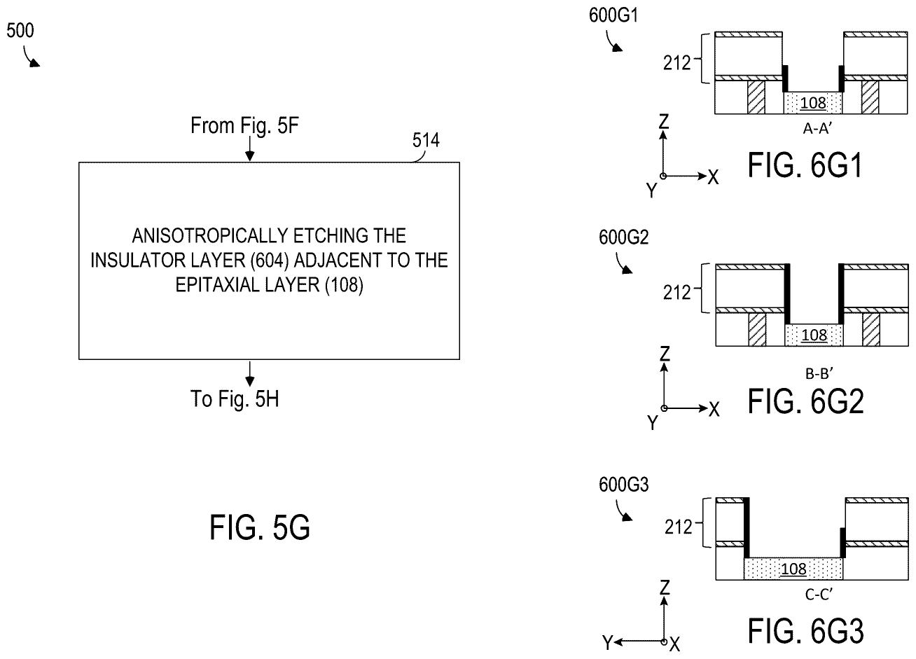

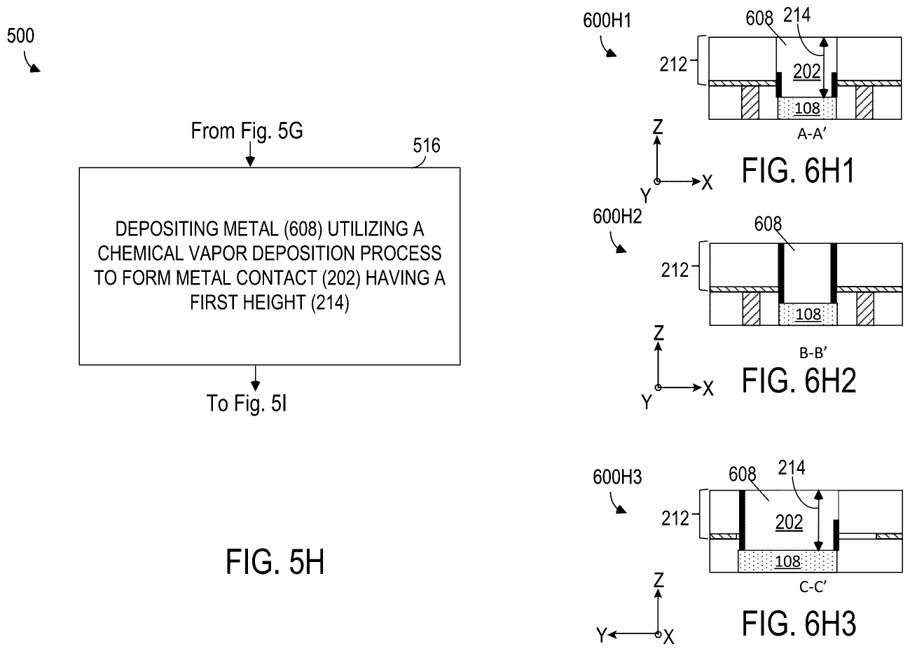

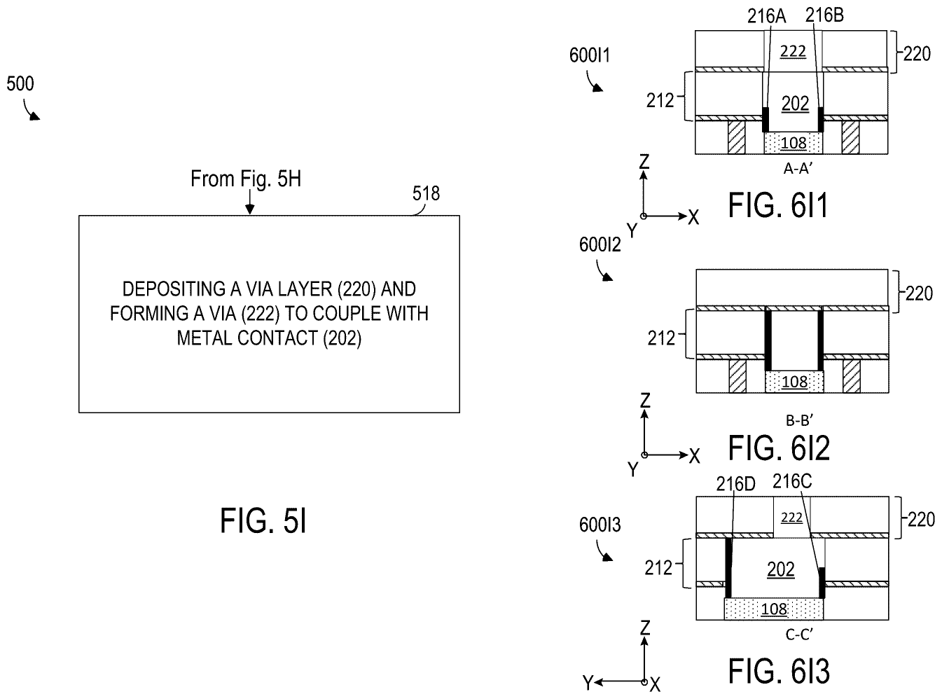

Other fabrication processes can also be employed to fabricate a die including a metal contact, such as the metal contacts 202, 210 of FIGS. 2A-2D and the metal contacts 300, 312 and 322 of FIGS. 3A-3C, having a reduced length sidewall(s) to promote connectivity with an adjacent via. In this regard, FIGS. 5A-5I is a flowchart of illustrating another exemplary fabrication process 500 for a die including a metal contact, such as the metal contacts of FIGS. 2A-2D, 3A-3C, having reduced length sidewalls to promote connectivity with an adjacent via. FIGS. 6A1-6I3 are exemplary fabrication stages during fabrication of the metal contact according to the fabrication process in FIGS. 5A-5I from three separate perspectives. The fabrication process 500 will be described in connection with the metal contact layer 212 and metal contact 202. Each fabrication stage in FIGS. 6A1-6I3 will be described from cut lines A-A′, B-B′, and C-C′ in FIG. 2A.

In this regard, as shown in fabrication stages 600A1-600A3 in FIGS. 6A1-6A3, an exemplary step in the fabrication process 500 is patterning a contact layer 212 to form an access 602 to an epitaxial layer 108 (block 502 in FIG. 5A). As shown in fabrication stages 600B1-600B3 in FIGS. 6B1-6B3, a next step in the fabrication process 600 can include depositing an insulation material by atomic layer deposition or chemical vapor deposition to form insulation sidewalls 216A-216D and an insulation layer 604 adjacent to the epitaxial layer 108 (block 504 in FIG. 5B). As shown in fabrication stages 600C1-600C3 in FIGS. 6C1-6C3, a next step in the fabrication process 600 can include depositing a photoresist 606 into the access 602 to the epitaxial layer 108 and baking the photoresist 606 (block 506 in FIG. 5C).

As shown in fabrication stages 600D1-600D3 in FIGS. 6D1-6D3, a next step in the fabrication process 500 can include masking portions of the photoresist 606 to expose sidewalls 216A-216C (block 508 in FIG. 5D). As shown in fabrication stages 600E1-600E3 in FIGS. 6E1-6E3, a next step in the fabrication process 500 can include isotopically etching portions of the sidewalls 216A-216C to reduce the height of the sidewalls 216A-216C to the second height 218 (block 510 in FIG. 5E). As shown in fabrication stages 600F1-600F3 in FIGS. 6F1-6F3, a next step in the fabrication process 500 can include ashing the photoresist 606 with plasma O₂ to remove the photoresist 606 (block 512 in FIG. 5F). As shown in fabrication stages 600G1-600G3 in FIGS. 6G1-6G3, a next step in the fabrication process 500 can include anisotropically etching the insulator layer 604 adjacent to the epitaxial layer 108 (block 514 in FIG. 5G). As shown in fabrication stages 600H1-600H3 in FIGS. 6H1-6H3, a next step in the fabrication process 500 can include depositing a metal 608 utilizing a chemical vapor deposition process to form the metal contact 202 having the first height 214 (block 516 in FIG. 5H). For example, the metal 608 may be tungsten and a conventional tungsten process may be used which utilizes a titanium nitride (TiN) barrier and a chemical vaper deposition process, and a chemical metal polishing (CMP) process. As shown in fabrication stages 600I1-600I3 in FIGS. 6I1-6I3, a next step in the fabrication process 500 can include depositing a via layer 220 and forming a via 222 to couple with the metal contact 202 (block 518 in FIG. 5I). Due to the increased surface area of the metal contact 202 by having sidewalls with reduced height, the via 222 may be formed utilizing a barrierless metal process such as a selective tungsten process.

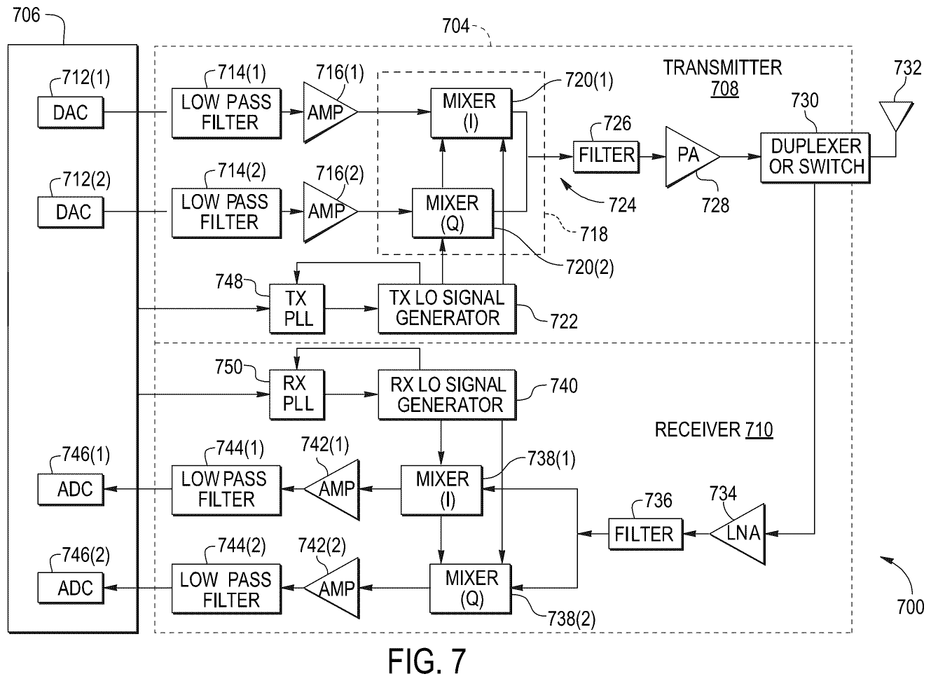

FIG. 7 is a block diagram of an exemplary wireless communications device that includes radio-frequency (RF) components deployed in an IC package, wherein the IC package includes a semiconductor die having a metal contact, including, but not limited to, the metal contacts in FIGS. 2A-2D, 3A-3C, having a reduced length sidewall(s) to promote connectivity with an adjacent via and fabricated according to the exemplary fabrication processes in FIGS. 4 and 5A-5I. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals (e.g., I and Q output currents) for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency up-conversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Down-conversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency up-conversion, while the RX LO signal generator 740 generates the I and Q RX LO signals used for frequency down-conversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

A semiconductor die having a metal contact, including, but not limited to, the metal contacts in FIGS. 2A-2D, 3A-3C, having a reduced length sidewall(s) to promote connectivity with an adjacent via and fabricated according to the exemplary fabrication processes in FIGS. 4 and 5A-5I as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

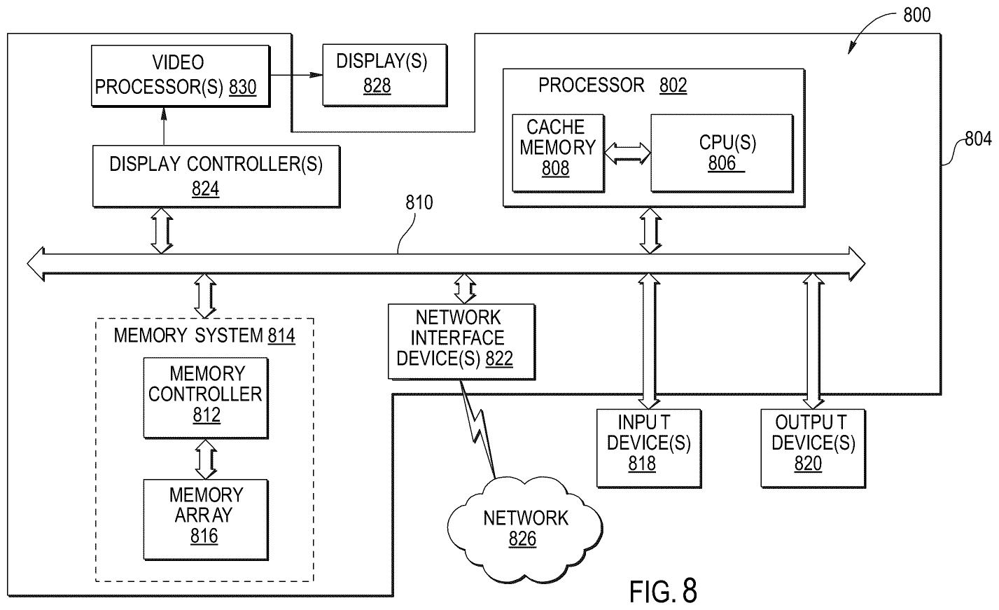

In this regard, FIG. 8 is a block diagram of an exemplary processor-based system that can include components deployed in an IC package, wherein the IC package includes a semiconductor die having a metal contact, including, but not limited to, the metal contacts in FIGS. 2A-2D, 3A-3C, having a reduced length sidewall(s) to promote connectivity with an adjacent via and fabricated according to the exemplary fabrication processes in FIGS. 4 and 5A-5I.

In this example, the processor-based system 800 includes a processor 802 deployed on a semiconductor die 804 including a metal contact, such as the metal contacts in FIGS. 2A-2D, 3A-3C, having reduced length sidewalls to promote connectivity with an adjacent via as disclosed herein and includes one or more central processing units (captioned as “CPUs” in FIG. 8) 806, which may also be referred to as CPU cores or processor cores. The processor 802 may have cache memory 808 coupled to the processor 802 for rapid access to temporarily stored data. The processor 802 is coupled to a system bus 810 and can intercouple server and client devices included in the processor-based system 800. As is well known, the processor 802 communicates with these other devices by exchanging address, control, and data information over the system bus 810. For example, the processor 802 can communicate bus transaction requests to a memory controller 812, as an example of a client device. Although not illustrated in FIG. 8, multiple system buses 810 could be provided, wherein each system bus 810 constitutes a different fabric.

Other server and client devices can be connected to the system bus 810 and deployed in a die including a metallization layer having a dielectric layer and a metal layer wherein the metal layer includes a resistive metal coupled to a via in the dielectric layer to decrease parasitic capacitance in the dielectric layer. As illustrated in FIG. 8, these devices can include a memory system 814 that includes the memory controller 812 and a memory array(s) 816, one or more input devices 818, one or more output devices 820, one or more network interface devices 822, and one or more display controllers 824, as examples. The input device(s) 818 can include any type of input device, including but not limited to input keys, switches, voice processors, etc. The output device(s) 820 can include any type of output device, including, but not limited to, audio, video, other visual indicators, etc. The network interface device(s) 822 can be any device configured to allow exchange of data to and from a network 826. The network 826 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 822 can be configured to support any type of communications protocol desired.

The processor 802 may also be configured to access the display controller(s) 824 over the system bus 810 to control information sent to one or more displays 828. The display controller(s) 826 sends information to the display(s) 828 to be displayed via one or more video processors 830, which process the information to be displayed into a format suitable for the display(s) 828. The display controller(s) 824 and/or the video processors 830 may comprise or be integrated into a GPU. The display(s) 828 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A semiconductor die, comprising:
   a transistor, comprising:
      an epitaxial layer of a first polarity extending in a first direction and a second direction orthogonal to the first direction;
   a contact layer extending in the first direction and the second direction adjacent to the epitaxial layer, the contact layer comprising:
      a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height; and
   a via layer extending in the first direction and the second direction adjacent to the contact layer, the via layer comprising a via coupled to the metal contact.
2. The semiconductor die of clause 1, wherein the second height is greater than or equal to ⅔ of the first height.
3. The semiconductor die of clause 1 or 2, wherein the via is proximal in one of the first direction and the second direction to the at least one of the plurality of sidewalls having the second height.
4. The semiconductor die of any of clauses 1-3, wherein the epitaxial layer is a source region.
5. The semiconductor die of any of clauses 1-3, wherein the epitaxial layer is a drain region.
6. The semiconductor die of any of clauses 1-5, wherein the transistor further comprises:
   a gate region extending in the first direction and the second direction and adjacent to the source region in the first direction.
7. The semiconductor die of clause 6, wherein the at least one of the plurality of sidewalls extends in the first direction and the third direction.
8. The semiconductor die of any of clauses 1-7, wherein the via is fabricated from a selective tungsten process and coupled to the metal contact.
9. The semiconductor die of any of clauses 1-8, wherein the metal contact comprises tungsten.
10. The semiconductor die of any of clauses 1-9, wherein the plurality of sidewalls comprises silicon nitride (SiN).
11. The semiconductor die of any of clauses 1-10, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
12. A method of fabricating a semiconductor die, comprising:
   fabricating a transistor, comprising:
      fabricating an epitaxial layer of a first polarity extending in a first direction and a second direction orthogonal to the first direction;
   fabricating a contact layer extending in the first direction and the second direction adjacent to the epitaxial layer, wherein fabricating the contact layer comprises:
      fabricating a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height; and
   fabricating a via layer extending in the first direction and the second direction adjacent to the contact layer, wherein fabricating the via layer comprises: fabricating a via coupled to the metal contact.
13. The method of clause 12, wherein the second height is greater than or equal to ⅔ of the first height.
14. The method of clause 12 or 13, wherein the via is proximal in one of the first direction and the second direction to the at least one of the plurality of sidewalls having the second height.
15. The method of any of clauses 12-14, wherein the epitaxial layer is a source region.
16. The method of any of clauses 12-14, wherein the epitaxial layer is a drain region.
17. The method of any of clauses 12-16, wherein fabricating the transistor further comprises:
   fabricating a gate region extending in the first direction and the second direction and adjacent to the source region in the first direction.
18. The method of any of clauses 14-17, wherein:
   fabricating the via includes utilizing a selective tungsten process.
19. A method of fabricating a semiconductor die, comprising:
   fabricating a transistor, comprising:
      fabricating an epitaxial layer of a first polarity extending in a first direction and a second direction orthogonal to the first direction;
   fabricating a contact layer extending in the first direction and the second direction adjacent to the epitaxial layer, wherein fabricating the contact layer comprises:
      patterning the contact layer to access the epitaxial layer;
      depositing an insulation material to form a plurality of sidewalls;
      etching portions of at least one of the plurality of sidewalls; and
      depositing metal to form a metal contact having a first height, the at least one of the plurality of sidewalls having a second height, wherein the second height is less than the first height; and
   fabricating a via layer extending in the first direction and the second direction adjacent to the contact layer, wherein fabricating the via layer comprises: fabricating a via coupled to the metal contact.
20. The method of clause 19, wherein the second height is greater than or equal to ⅔ of the first height.

What is claimed is:

1. A semiconductor die, comprising:
a transistor, comprising:
an epitaxial layer of a first polarity extending in a first direction and a second direction orthogonal to the first direction;
a contact layer extending in the first direction and the second direction adjacent to the epitaxial layer, the contact layer comprising:
a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height; and
a via layer extending in the first direction and the second direction adjacent to the contact layer, the via layer comprising a via coupled to the metal contact.

2. The semiconductor die of claim 1, wherein the second height is greater than or equal to ⅔ of the first height.

3. The semiconductor die of claim 1, wherein the via is proximal in one of the first direction and the second direction to the at least one of the plurality of sidewalls having the second height.

4. The semiconductor die of claim 1, wherein the epitaxial layer is a source region.

5. The semiconductor die of claim 1, wherein the epitaxial layer is a drain region.

6. The semiconductor die of claim 4, wherein the transistor further comprises:
a gate region extending in the first direction and the second direction and adjacent to the source region in the first direction.

7. The semiconductor die of claim 6, wherein the at least one of the plurality of sidewalls extends in the first direction and the third direction.

8. The semiconductor die of claim 1, wherein the via is fabricated from a selective tungsten process and coupled to the metal contact.

9. The semiconductor die of claim 1, wherein the metal contact comprises tungsten.

10. The semiconductor die of claim 1, wherein the plurality of sidewalls comprises silicon nitride (SiN).

11. The semiconductor die of claim 1, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

12. A method of fabricating a semiconductor die, comprising:
fabricating a transistor, comprising:
fabricating an epitaxial layer of a first polarity extending in a first direction and a second direction orthogonal to the first direction;
fabricating a contact layer extending in the first direction and the second direction adjacent to the epitaxial layer, wherein fabricating the contact layer comprises:
fabricating a metal contact adjacent to the epitaxial layer and having a first height in a third direction orthogonal to the first direction and the second direction, the metal contact comprising a plurality of sidewalls extending in the third direction from the epitaxial layer, wherein at least one of the plurality of sidewalls has a second height, wherein the second height is less than the first height; and
fabricating a via layer extending in the first direction and the second direction adjacent to the contact layer, wherein fabricating the via layer comprises:
fabricating a via coupled to the metal contact.

13. The method of claim 12, wherein the second height is greater than or equal to ⅔ of the first height.

14. The method of claim 12, wherein the via is proximal in one of the first direction and the second direction to the at least one of the plurality of sidewalls having the second height.

15. The method of claim 12, wherein the epitaxial layer is a source region.

16. The method of claim 12, wherein the epitaxial layer is a drain region.

17. The method of claim 15, wherein fabricating the transistor further comprises:
fabricating a gate region extending in the first direction and the second direction and adjacent to the source region in the first direction.

18. The method of claim 14, wherein:
fabricating the via includes utilizing a selective tungsten process.

19. A method of fabricating a semiconductor die, comprising:
fabricating a transistor, comprising:
fabricating an epitaxial layer of a first polarity extending in a first direction and a second direction orthogonal to the first direction;
fabricating a contact layer extending in the first direction and the second direction adjacent to the epitaxial layer, wherein fabricating the contact layer comprises:
patterning the contact layer to access the epitaxial layer;
depositing an insulation material to form a plurality of sidewalls;
etching portions of at least one of the plurality of sidewalls; and
depositing metal to form a metal contact having a first height, the at least one of the plurality of sidewalls having a second height, wherein the second height is less than the first height; and
fabricating a via layer extending in the first direction and the second direction adjacent to the contact layer, wherein fabricating the via layer comprises:
fabricating a via coupled to the metal contact.

20. The method of claim 19, wherein the second height is greater than or equal to ⅔ of the first height.
